(19) United States
(12) Patent Application Publication
(10) Pub. No.: US 2022/0270853 A1
(43) Pub. Date: Aug. 25, 2022

(54) APPARATUS FOR DEPOSITING TWO-DIMENSIONAL MATERIALS

(71) Applicant: Samsung Electronics Co., Ltd., Suwon-si (KR)

(72) Inventors: Changseok Lee, Gwacheon-si (KR); Keunwook Shin, Yongin-si (KR); Hyeonjin Shin, Suwon-si (KR)

(73) Assignee: Samsung Electronics Co., Ltd., Suwon-si (KR)

(21) Appl. No.: 17/523,339

(22) Filed: Nov. 10, 2021

(30) Foreign Application Priority Data
Feb. 19, 2021 (KR) 10-2021-0022696

(51) Int. Cl. H01J 37/32; C23C 16/505; C23C 16/455; C23C 16/458; C23C 16/46; C23C 16/34; C23C 16/30

(52) U.S. Cl. CPC H01J 37/3244; H01J 37/3211; H01J 37/32724; C23C 16/505; C23C 16/4557; C23C 16/4584; C23C 16/46; C23C 16/342; C23C 16/305; H01J 2237/3323; H01J 2237/3321

(57) ABSTRACT

An apparatus for depositing a two-dimensional material includes a chamber, a stage provided in the chamber, a dielectric window including a first surface facing the stage and a second surface provided on a side opposite to the first surface, a planar high-frequency antenna provided on the second surface of the dielectric window, and a first gas nozzle configured to provide a source gas into the chamber, wherein an alternating current electric signal having a frequency of about 1 MHz to about 1 GHz is applied to the planar high-frequency antenna.

### CROSS-REFERENCE TO RELATED APPLICATION

This application claims the benefit of Korean Patent Application No. 10-2021-0022696, filed on Feb. 19, 2021, in the Korean Intellectual Property Office, the entire disclosure of which is incorporated herein by reference.

### BACKGROUND

### 1. Field

The disclosure relates to an apparatus for depositing a two-dimensional material.

### 2. Description of the Related Art

A two-dimensional material may be formed by a deposition process. To be applied in a semiconductor process, the deposition process for the two-dimensional material may be required to be performed at a low temperature. The low-temperature deposition process may include a chemical vapor deposition process based on high-density (for example, ion density of 10¹¹/cm³ or more) plasma.

The chemical vapor deposition process based on high-density plasma may be divided into several types according to a plasma forming method. Some plasma deposition processes may damage a two-dimensional material, a deposition substrate, a chamber, or so on, and may also provide low deposition uniformity.

A chemical vapor deposition process of an inductively-coupled plasma method forms a high-density plasma in an inner space of a chamber, thereby doing less damage to a surface of a chamber compared to a microwave plasma method of generating plasma in a local area. In addition, the chemical vapor deposition process of the inductively-coupled plasma method may be performed at a low pressure, and thus, anisotropy in a travel direction of deposited ions may be increased. Accordingly, deposition uniformity may be increased.

The chemical vapor deposition process of the inductively-coupled plasma method may be divided into a flat type and a cylindrical type according to a shape of a coil. A coil of the flat type may extend spirally. A coil of the cylinder type may extend in a solenoid shape. Between the two types, the flat type may be more suitable for a large area to increase deposition uniformity.

### SUMMARY

Provided are apparatuses for depositing a two-dimensional material that increase deposition uniformity.

Provided are apparatuses for depositing a two-dimensional material that limit and/or prevent a dielectric window from being contaminated.

Provided are apparatuses for depositing a two-dimensional material that form a high-quality deposition film.

However, the disclosure is not limited thereto.

Additional aspects will be set forth in part in the description which follows and, in part, will be apparent from the description, or may be learned by practice of the presented embodiments of the disclosure.

According to an embodiment, an apparatus for depositing a two-dimensional material includes a chamber, a stage in the chamber, a dielectric window including a first surface facing the stage and a second surface on a side opposite to the first surface, a planar high-frequency antenna on the second surface of the dielectric window, and a first gas nozzle configured to provide a source gas into the chamber, wherein an alternating current electric signal having a frequency of about 1 MHz to about 1 GHz may be applied to the planar high-frequency antenna.

In some embodiments, the apparatus may further include a second gas nozzle in a region adjacent to an edge of the first surface of the dielectric window, and the second gas nozzle may provide an inert gas in the chamber.

In some embodiments, the apparatus may further include a third gas nozzle in a region adjacent to a center of the first surface of the dielectric window, and the third gas nozzle may provide an inert gas in the chamber.

In some embodiments, the apparatus may further include a plurality of first gas nozzles. The plurality of first gas nozzles may be arranged at regular intervals in a circumferential direction of an inner surface of the chamber.

In some embodiments, the first gas nozzle may further provide an inert gas in the chamber.

In some embodiments, the apparatus may further include a nozzle heating unit configured to heat the first gas nozzle.

In some embodiments, the nozzle heating unit may heat the first gas nozzle to about 700° C. to about 1,000° C.

In some embodiments, the apparatus may further include a window heating unit configured to heat the dielectric window.

In some embodiments, the window heating unit may heat the dielectric window to about 700° C. to about 1,000° C.

In some embodiments, the stage may perform a rotational motion, an ascending motion, or a descending motion.

In some embodiments, a basic bias power less than or equal to about 3,000 watts may be applied to the stage.

In some embodiments, an additional bias power less than or equal to about 100 watts may be applied to the stage.

In some embodiments, the first gas nozzle may be at a level spaced apart from the planar high-frequency antenna by a first distance in a direction from the planar high-frequency antenna toward the dielectric window, and the first distance may be 5% to 95% of a distance between the planar high-frequency antenna and the stage.

In some embodiments, the apparatus may further include a deposition substrate on the stage, and a stage heater configured to heat the deposition substrate.

In some embodiments, the stage heater may heat the deposition substrate to about 550° C. or less.

In some embodiments, the dielectric window may include a high-density insulating material.

In some embodiments, the dielectric window may include a quartz sapphire, boron nitride, or a ceramic material.

In some embodiments, the chamber may include an aluminum-based metal, a stainless steel-based metal, an alloy, an oxide, or a nitride.

In some embodiments, the apparatus may further include a deposition substrate located on the stage to provide a region on which a two-dimensional material is deposited. The two-dimensional material may include graphene, a two-dimensional transition metal chalcogen compound, amorphous boron nitride (a-BN), cubic boron nitride (c-BN), or hexagonal boron nitride (h-BN), and the two-dimensional transition metal chalcogen compound may include MoS₂, MoSe₂, MoTe₂, WS₂, WSe₂, PdSe₂, PdTe₂, PtSe₂, ReSe₂, VSe₂, phosphorene, borophene, stanene, tellurene, or mxene.

In some embodiments, the first gas nozzle may discharge the source gas to a position spaced apart from the planar high-frequency antenna by 5% to 95% of a distance between the planar high-frequency antenna and the stage.

### BRIEF DESCRIPTION OF THE DRAWINGS

The above and other aspects, features, and advantages of certain embodiments of the disclosure will be more apparent from the following description taken in conjunction with the accompanying drawings, in which:

FIG. 1 is a cross-sectional view of an apparatus for depositing a two-dimensional material according to an example embodiment of the disclosure.

FIG. 2 is a plan view of a gas injector of FIG. 1;

FIGS. 3 and 4 are views illustrating two-dimensional materials formed by respectively supplying source gases to regions having different densities within a plasma;

FIG. 5 is a conceptual diagram of an apparatus for depositing a two-dimensional material according to an example embodiment;

FIG. 6 is a plan view of a first gas injector of FIG. 5;

FIG. 7 is a plan view of a second gas injector of FIG. 5;

FIG. 8 is a plan view of a third gas injector of FIG. 5; and

FIG. 9 is a cross-sectional view of an apparatus for depositing a two-dimensional material according to an example embodiment.

### DETAILED DESCRIPTION

Reference will now be made in detail to embodiments, examples of which are illustrated in the accompanying drawings, wherein like reference numerals refer to like elements throughout. In this regard, the presented embodiments may have different forms and should not be construed as being limited to the descriptions set forth herein. Accordingly, the embodiments are merely described below, by referring to the figures, to explain aspects. As used herein, the term “and/or” includes any and all combinations of one or more of the associated listed items. Expressions such as “at least one of,” when preceding a list of elements, modify the entire list of elements and do not modify the individual elements of the list.

Hereinafter, example embodiments of the disclosure will be described in detail with reference to the accompanying drawings. In the following drawings, the same reference numerals refer to the same components, and sizes of respective components in the drawings may be exaggerated for clear and convenient description. In addition, the embodiments to be described below are merely examples, and various modifications may be made from the embodiments.

Hereinafter, a term described as “on” may include not only a portion directly above in contact therewith, but also a portion above not in contact therewith.

A singular expression includes plural expressions unless the context clearly indicates otherwise. In addition, when it is described that a portion “includes” a certain component, this indicates that the portion further includes another component rather than excluding another component unless specifically stated to the contrary.

In addition, terms such as “ . . . unit or portion” described in the specification indicate a unit that processes at least one function or operation.

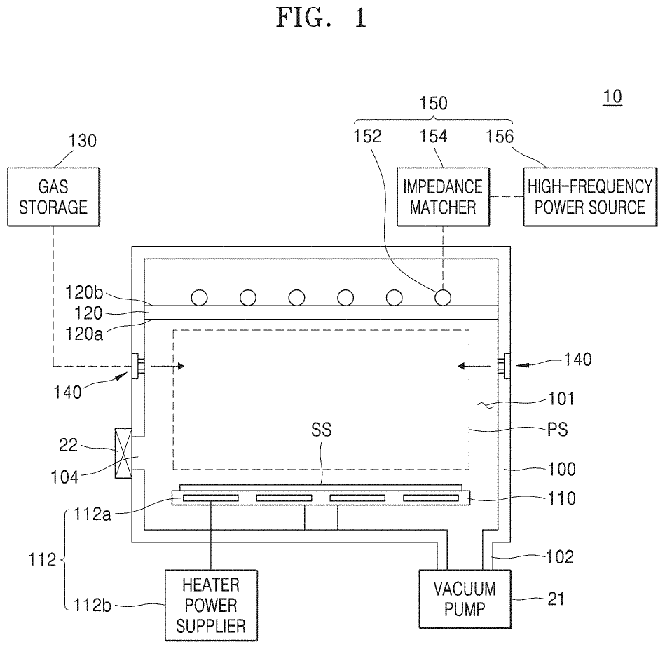

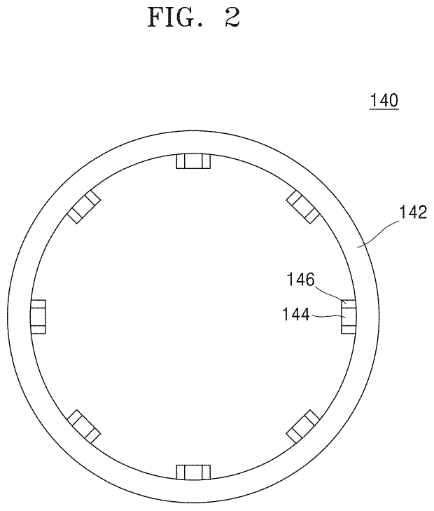

FIG. 1 is a cross-sectional view of an apparatus 10 for depositing a two-dimensional material according to an example embodiment of the disclosure. FIG. 2 is a plan view of a gas injector of FIG. 1.

Referring to FIG. 1, the apparatus 10 for depositing a two-dimensional material may be provided. The apparatus 10 for depositing a two-dimensional material may include a chamber 100, a stage 110, a stage heater 112, a dielectric window 120, a gas storage 130, a gas injector 140, and a plasma generator 150.

The apparatus 10 for depositing a two-dimensional material may include a plasma deposition apparatus that deposits a two-dimensional material on a deposition substrate SS in the chamber 100 by using plasma PS. For example, the two-dimensional material may include graphene, a two-dimensional transition metal chalcogen compound (for example, MoS₂, MoSe₂, MoTe₂, WS₂, WSe₂, PdSe₂, PdTe₂, PtSe₂, ReSe₂, VSe₂, Phosphorene, Borophene, Stanene, Tellurene, or Mxene), amorphous boron nitride (a-BN), cubic boron nitride (c-BN), or hexagonal boron nitride (h-BN).

The chamber 100 may be a plasma deposition chamber that performs a plasma deposition process. For example, the chamber 100 may include an aluminum (Al)-based metal, a stainless steel (SUS)-based metal, or an alloy thereof. For example, the chamber 100 may include oxide or nitride of an Al-based metal, or nitride or oxide of a SUS-based metal.

The deposition substrate SS may provide a region in which a two-dimensional material is deposited. The deposition substrate SS may include a semiconductor structure generated by another semiconductor process. For example, the deposition substrate SS may include layers and patterns formed of a semiconductor material, an insulating material, and a metal material. In example embodiments, the apparatus 10 for depositing a two-dimensional material may directly grow a graphene film on the deposition substrate SS by using the plasma PS.

The chamber 100 may define an inner space 101. Hereinafter, the inside of the chamber 100 is referred to as an inner space 101. The inner space 101 may be a space in which the plasma PS is generated and a two-dimensional material is deposited on the deposition substrate SS by using the generated plasma PS. An exhaust pipe 102 may be provided below the chamber 100, and the exhaust pipe 102 may be connected to a vacuum pump 21. The vacuum pump 21 may adjust a pressure of the inner space 101 so that a pressure atmosphere suitable for performing a plasma generating process and a deposition process using the plasma PS is formed in the inner space 101. An opening 104 for carrying in or carrying out the deposition substrate SS may be provided in a sidewall of the chamber 100. A gate valve 22 for opening and closing the opening may be provided on the opening.

The stage 110 may be provided under the inner space 101. The stage 110 may provide a region in which the deposition substrate SS is located. The stage 110 may support the deposition substrate SS during a plasma treatment process. For example, the stage 110 may include aluminum nitride (AlN), Al, silicon carbide (SiC), stainless steel, or a combination thereof. In an example embodiment, the stage 110 may have an electrode function during a deposition process. A basic bias power may be applied to the stage 110. The basic bias power may be used for generating plasma. For example, the basic bias power may be a radio frequency (RF) power less than or equal to about 3,000 watts. In addition, an additional bias power may be applied to the stage 110. The additional bias power may strongly attract ions and radicals in the plasma to a surface of the deposition substrate SS. For example, the additional bias power may be an RF power less than or equal to about 100 watts. In a case in which the deposition substrate SS is an insulating substrate, when the basic bias power and the additional bias power are applied to the stage 110, a nucleation process is rapidly performed on a surface of the deposition substrate SS to reduce an incubation time. The incubation time may refer to a time until a reaction between the surface of the deposition substrate SS and a deposition source starts after a source gas is supplied. When a deposition surface is not flat and has a pattern structure, non-uniformity of deposition according to the pattern structure may be reduced by a bias, and thus, step coverage may be improved. In example embodiments, the stage 110 may rotate during a deposition process. As the deposition substrate SS rotates together with the stage 110, deposition uniformity may be increased. In example embodiments, the stage 110 may perform an ascending motion and a descending motion. A height of the stage 110 may be adjusted to increase deposition uniformity. For example, when areas where high-density plasma PS is generated are different from each other depending on heights, the stage 110 may move the deposition substrate SS to a height in which the area where the high-density plasma PS is generated is largest.

The stage heater 112 may heat the deposition substrate SS supported on the stage 110. For example, the stage heater 112 may be configured to heat the deposition substrate SS to a temperature suitable for processing the deposition substrate SS during a plasma treatment process. The deposition substrate SS may include a semiconductor structure generated by another semiconductor process. For example, the deposition substrate SS may include a semiconductor material, an insulating material, and a metal material. The stage heater 112 may heat the deposition substrate SS at a low temperature so that the semiconductor structure generated by another semiconductor process is not degraded. For example, the stage heater 112 may heat the deposition substrate SS to about 550° C. or less. Accordingly, the two-dimensional material deposition process according to the disclosure may be compatible with other semiconductor processes. In other words, the two-dimensional material deposition process according to the disclosure may be included in one of other semiconductor processes. The apparatus 10 for depositing a two-dimensional material according to the disclosure uses plasma, and thus, a deposition process may be smoothly performed even when the deposition substrate SS is heated to a low temperature.

The stage heater 112 may include a heating electrode 112a and a heater power supplier 112b. The heating electrode 112a may be embedded in the stage 110. For example, the heating electrode 112a may have a concentric circular pattern or a spiral pattern based on a central axis of the stage 110. The heating electrode 112a may include a conductor. For example, the heating electrode 112a may include a metal such as tungsten (W), copper (Cu), nickel (Ni), molybdenum (Mo), titanium (Ti), a nickel-chromium (Ni—Cr) alloy, or a nickel-aluminum (Ni—Al) alloy, or conductive ceramic such as tungsten carbide (WC), molybdenum carbide (MoC), or titanium nitride (TiN).

The heater power supplier 112b may be electrically connected to the heating electrode 112a to supply a power thereto. For example, the heater power supplier 112b may heat the heating electrode 112a by applying an alternating current (AC) voltage to the heating electrode 112a. Temperatures of the stage 110 and the deposition substrate SS supported on the stage 110 may be adjusted by the heated heating electrode 112a. The heating power supplier 112b may include circuitry for heating the heating electrode 112a.

The gas storage 130 may store a process gas. The process gas may be required during a two-dimensional material deposition process. For example, the process gas may include a source gas and an inert gas for generating plasma. The process gas may further include other gases as necessary in addition to the gases listed in the example. When the two-dimensional material includes carbon, the source gas may include a carbon-containing gas. For example, the carbon-containing gas includes ethylene (C₂H₄), methane (CH₄), ethane (C₂H₆), propane (C₃H₈), propylene (C₃H₆), acetylene (C₂H₂), methanol (CH₃OH), or ethanol (C₂H₅OH). For example, the inert gas may include an argon (Ar) gas, helium (He), a neon (Ne) gas, a crypto (Kr) gas, or a xenon (Xe) gas. The gas storage 130 may include a plurality of storage sources (e.g., containers such as cylinders) for storing respective gases. For example, the gas storage 130 may include an inert gas storage source for storing an inert gas and a source gas storage source including a source gas.

The gas injector 140 may be provided in a sidewall of the chamber 100. The gas injector 140 may provide a process gas to the inner space 101. For example, the gas injector 140 may include a gas transfer pipe 142, a gas nozzle 144, and a nozzle heating unit 146. The gas transfer pipe 142 may receive a process gas from the gas storage 130 and provide the process gas to the gas nozzle 144. The gas transfer pipe 142 may extend in a circumferential direction of an inner surface of the chamber 100. The gas transfer pipe 142 may have a ring shape. For example, the gas transfer pipe 142 may have a circular ring shape.

The gas nozzle 144 may be provided inside the gas transfer pipe 142. The gas nozzle 144 may receive a process gas from the gas storage 130 and discharge the process gas to the inner space 101. The gas nozzle 144 may provide the process gas to a region spaced apart from the dielectric window 120. For example, the gas nozzle 144 may discharge the process gas to a position spaced apart from a high-frequency antenna 152 by 5% to 95% of a distance between the high-frequency antenna 152 and the stage 110. In one example, the gas nozzle 144 may be at a position spaced apart from the high-frequency antenna 152 by 5% to 95% of the distance between the high-frequency antenna 152 and the stage 110. The dielectric window 120 may have a thickness smaller than 5% of the distance between the high-frequency antenna 152 and the stage 110.

In example embodiments, a plurality of gas nozzles 144 may be provided. The plurality of gas nozzles 144 may be arranged along the gas transfer pipe 142. The plurality of gas nozzles 144 may be arranged in the circumferential direction of the inner surface of the chamber 100. For example, the plurality of gas nozzles 144 may be arranged at regular intervals.

The nozzle heating unit 146 may heat the gas nozzle 144. For example, the nozzle heating unit 146 may include a hot-filament wound around the gas nozzle 144. When the plurality of gas nozzles 144 are provided, a plurality of hot-filaments may be provided to the plurality of gas nozzles 144, respectively. The nozzle heating unit 146 may heat the gas nozzle 144 so that a source gas discharged from the gas nozzle 144 is decomposed by heat. For example, the nozzle heating unit 146 may heat the gas nozzle 144 to about 700° C. to about 1,000° C. according to the pyrolysis temperature of the source gas.

The dielectric window 120 may be provided on the inner space 101. The dielectric window 120 may face the stage 110. The dielectric window 120 may include a first surface 120a facing the stage 110 and a second surface 120b located opposite to the first surface 120a. The dielectric window 120 may include a high-density insulating material. For example, the dielectric window 120 may include quartz, sapphire, boron nitride, or ceramic.

The plasma generator 150 may generate the plasma PS in the inner space 101. For example, an electric field formed in the inner space 101 by the plasma generator 150 may convert the process gas into plasma PS. The plasma generator 150 may generate high-density plasma PS in the inner space 101 by using a direct plasma method. The direct plasma method may refer to a method of directly generating plasma in the inner space 101. The plasma generator 150 may convert the process gas in the inner space 101 into the high-density plasma PS by using an inductively coupled plasma method. The plasma generator 150 may include the high-frequency antenna 152, a high-frequency power source 156, and an impedance matcher 154.

The high-frequency antenna 152 may be provided on the second surface 120b of the dielectric window 120. The high-frequency antenna 152 may include a planar high-frequency antenna. For example, the high-frequency antenna 152 may have a coil shape such as a spiral circle or a concentric circle. The high-frequency antenna 152 may be electrically connected to the high-frequency power source 156 through the impedance matcher 154. The high-frequency power source 156 may output high-frequency power suitable for generating plasma. For example, the high-frequency power source 156 may apply an AC electrical signal (for example, an AC current signal or an AC voltage signal) having a frequency of about 1 MHz to about 1 GHz to the high-frequency antenna 152 to generate the high-density plasma PS. The impedance matcher 154 may be configured to perform impedance matching between the high-frequency power source 156 and the high-frequency antenna 152. The impedance matcher 154 may include power circuitry for performing impedance matching between the high-frequency power source 156 and the high-frequency antenna 152.

Hereinafter, a deposition process is described. A process gas supplied from the gas storage 130 may be discharge into the inner space 101 through the gas nozzle 144. The process gas (for example, a source gas and an inert gas for generating plasma) may be uniformly diffused into the inner space 101. A magnetic field may be formed in the inner space 101 by passing through the dielectric window 120 by an electric current flowing through the high-frequency antenna 152. The magnetic field may change over time due to a high-frequency current applied to the high-frequency antenna 152. An induced electric field may be generated in the inner space 101 due to a temporal change of the magnetic field, and the process gas may be converted into plasma by the induced electric field. When the source gas is converted into plasma, source radicals (for example, carbon radicals) for deposition may be generated. The source radicals for deposition may be moved to a surface of the deposition substrate SS by diffusion. The source radicals for deposition may be physically adsorbed on a surface of the deposition substrate SS or may combine with atoms on the surface of the deposition substrate SS. Accordingly, a two-dimensional material may be deposited on the deposition substrate SS.

When a source gas is provided in a region adjacent to the dielectric window 120, contaminants may accumulate on the dielectric window 120. According to the disclosure, the source gas may be provided in a region spaced apart from the dielectric window 120 to limit and/or prevent the dielectric window 120 from being contaminated.

The closer to the high-frequency antenna, the higher the plasma energy, and thus, plasma energy may be the highest in a region adjacent to the dielectric window 120. When the source gas is provided to the region adjacent to the dielectric window 120 (that is, a region where plasma energy is high), a reaction is too active in a gas phase, and thus, materials to be deposited may be combined in the form of clusters or particles to fall on the substrate SS. According to the disclosure, a source gas may be provided in a region spaced apart from the dielectric window 120, and thus, materials to be deposited may not be combined in the form of clusters or particles, but may be provided to the deposition substrate SS. Accordingly, a deposition film having high deposition uniformity and high quality may be formed.

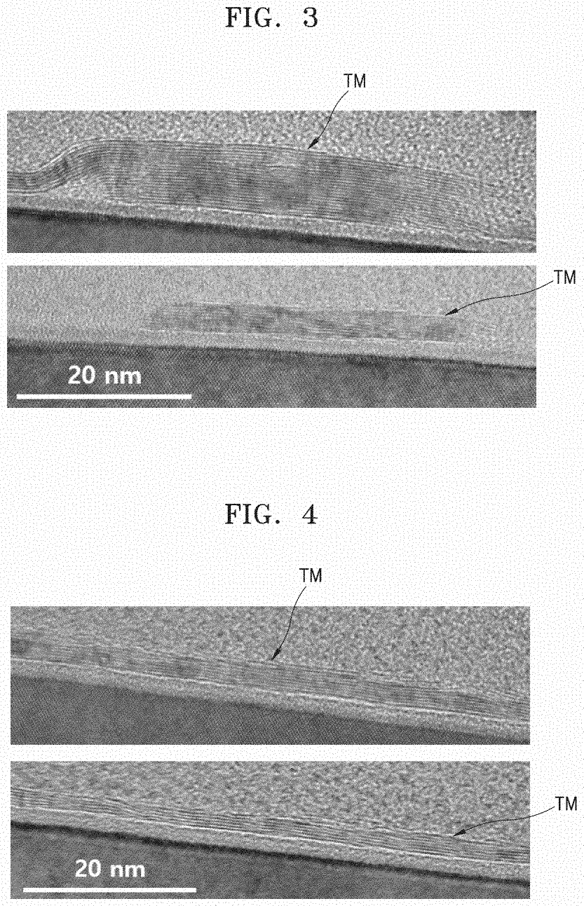

FIGS. 3 and 4 are views illustrating two-dimensional materials formed by supplying a source gas to regions having different densities in a plasma, respectively.

Referring to FIG. 3, the source gas is provided in a high-density plasma region to form a two-dimensional material. The two-dimensional material tends to grow vertically. It is difficult for a two-dimensional material to form a stable layer structure only by providing the source gas to the high-density plasma region.

Referring to FIG. 4, the source gas is provided in a low-density plasma region to form a two-dimensional material. The two-dimensional material is formed to have a stable layer structure.

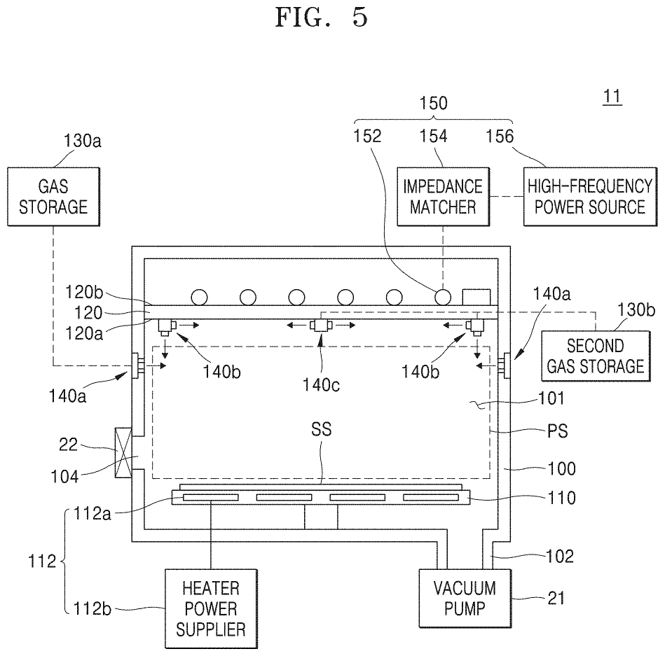

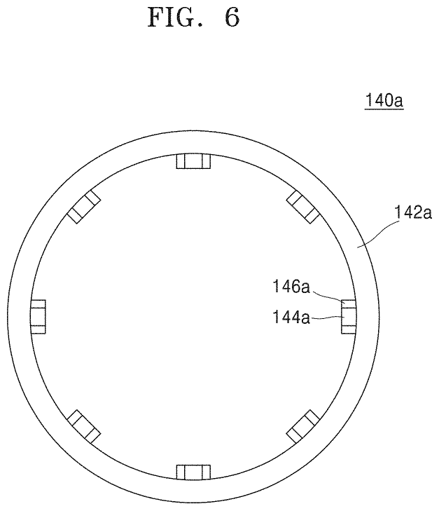

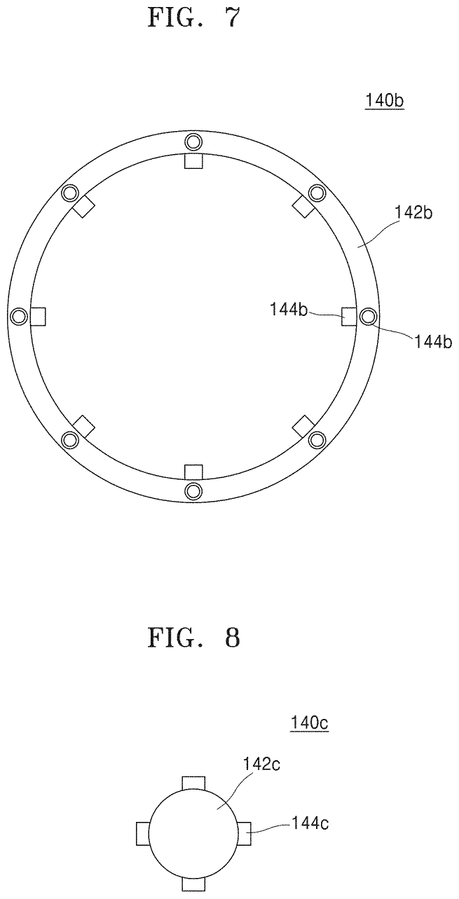

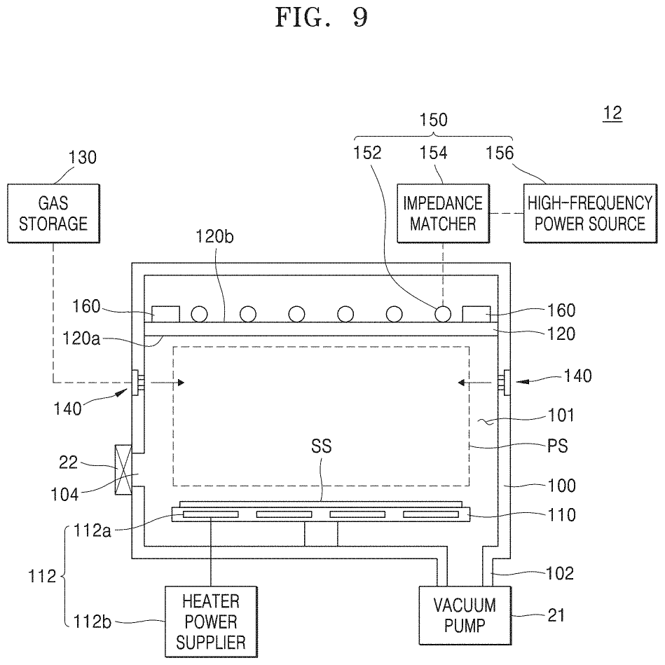

FIG. 5 is a conceptual diagram of an apparatus 11 for depositing a two-dimensional material according to an example embodiment. FIG. 6 is a plan view of the first gas injector of FIG. 5. FIG. 7 is a plan view of a second gas injector of FIG. 5. FIG. 8 is a plan view of a third gas injector of FIG. 5. For the sake of brief description, content substantially the same as the content described with reference to FIGS. 1 and 2 may not be described.

Referring to FIGS. 5 to 8, the apparatus 11 for depositing a two-dimensional material may be provided. The apparatus 11 for depositing a two-dimensional material may include a chamber 100, a stage 110, a stage heater 112, a dielectric window 120, a first gas storage 130a (e.g., container), a first gas injector 140a, and a second gas storage 130b (e.g., container), a second gas injector 140b, a third gas injector 140c, and a plasma generator 150. The chamber 100, the stage 110, the stage heater 112, the dielectric window 120, and the plasma generator 150 may be, respectively, substantially the same as the chamber 100, the stage 110, the stage heater 112, the dielectric window 120, and the plasma generator 150 described with reference to FIGS. 1 and 2.

The first gas injector 140b may include a second gas transfer pipe 142b, a second gas nozzle 144b, and a second nozzle heating unit 146b. The first gas injector 140a may be substantially the same as the gas injector 140 described with reference to FIGS. 1 to 2.

The first gas storage 130a may store a source gas. The first gas storage 130a may provide the source gas to the first gas injector 140a. The source gas may be provided to the inner space 101 by the first gas nozzle 144a. The source gas may be provided in a region spaced apart from the dielectric window 120 to limit and/or prevent the dielectric window 120 from being contaminated and to form a deposition film with high deposition uniformity and high quality.

Unlike the first gas storage 130a, the second gas storage 130b may store process gases other than the source gas among the process gases. For example, the second gas storage 130b may store an inert gas for generating plasma. For example, the second gas storage 130b may store an Ar gas, He, a Ne gas, a Kr gas, or a Xe gas.

The second gas injector 140b may include a second gas transfer pipe 142b and a second gas nozzle 144b. The second gas transfer pipe 142b may be provided on a first surface 120a of the dielectric window 120. For example, the second gas transfer pipe 142b may be in a region adjacent to an edge of the first surface 120a. The second gas transfer pipe 142b may have a ring shape extending on the first surface 120a of the dielectric window 120. For example, the second gas transfer pipe 142b may have a circular ring shape. The second gas transfer pipe 142b may be connected to the second gas storage 130b. The other process gas may be provided from the second gas storage 130b to the second gas transfer pipe 142b.

The second gas nozzle 144b may be provided inside or below the second gas transfer pipe 142b. The second gas nozzle 144b may receive the other process gas from the second gas storage 120b and discharge the process gas to the inner space 101. For example, the second gas nozzle 144b may discharge an inert gas such as argon an Ar gas, He, a Ne gas, a Kr gas, or a Xe gas. In example embodiments, a plurality of second gas nozzles 144b may be provided. The plurality of second gas nozzles 144b may be arranged along the second gas transfer pipe 142b. For example, the plurality of second gas nozzles 144b may be arranged at regular intervals. The plurality of second gas nozzles 144b may be provided inside and below the second gas transfer pipe 142b.

The third gas injector 140c may include a third gas transfer pipe 142c and a second gas nozzle 144c. The third gas transfer pipe 142c and the third gas nozzle 144c may be provided on the first surface 120a of the dielectric window 120. For example, the third gas transfer pipe 142c and the third gas nozzle 144c may be in a region adjacent to the center of the first surface 120a. For example, the third gas transfer pipe 142c may have a circular shape. The third gas transfer pipe 142c may be connected to the second gas storage 130b. The other process gas may be provided from the second gas storage 130b to the third gas transfer pipe 142c.

The third gas nozzle 144c may be arranged along a rim of the third gas transfer pipe 142c. For example, the third gas nozzles 144c may be arranged at regular intervals. The third gas nozzle 144c may provide the other process gas in the third gas transfer pipe 142c to the inner space 101 of the chamber 100. For example, the third gas nozzle 144c may discharge an inert gas into the inner space 101.

An electric field formed when a high-frequency current is applied to the high-frequency antenna 152 may be stronger as the electric field is closer to the high-frequency antenna 152. The second gas nozzle 144b and the third gas nozzle 144c according to the disclosure may be on the first surface 120a of the dielectric window 120 to provide an inert gas to a region adjacent to the high-frequency antenna 152. Therefore, plasma may be easily generated.

FIG. 9 is a cross-sectional view of an apparatus 12 for depositing a two-dimensional material according to an example embodiment. For the sake of brief description, content substantially the same as the content described with reference to FIGS. 1 and 2 may not be described.

Referring to FIG. 9, the apparatus 12 for depositing a two-dimensional material may be provided. The apparatus 12 for depositing a two-dimensional material may include a chamber 100, a stage 110, a dielectric window 120, a gas storage 130, a gas injector 140, and a plasma generator 150, and a window heating unit 160. The chamber 100, the stage 110, the dielectric window 120, the gas storage 130, the gas injector 140, and the plasma generator 150 may be, respectively, substantially the same as the chamber 100, the stage 110, the dielectric window 120, the gas storage 130, the gas injector 140, and the plasma generator 150 described with reference to FIGS. 1 and 2.

The window heating unit 160 may be provided on a second surface 120b of the dielectric window 120. The window heating unit 160 may heat the dielectric window 120. For example, the window heating unit 160 may heat the dielectric window 120 to about 700° C. to about 1,000° C. The window heating unit 160 may include a circuit for heating the dielectric window 120.

In a plasma-type deposition apparatus, as a deposition process proceeds, contaminants may accumulate on a surface thereof. A cleaning process using plasma may be performed to remove contaminants. The disclosure may perform a cleaning process using heat by heating the dielectric window 120 by using the window heating unit 160. If necessary, a cleaning process using plasma and/or a cleaning process using heat may be performed to effectively remove contaminants.

The above description on the embodiments of the technical idea of the disclosure provides an example for describing the technical idea of the disclosure. Therefore, the technical idea of the disclosure is not limited to the above-described embodiments, and it is clear that various modifications and changes such as a combination of the above-described embodiments may be made by those skilled in the art within the technical scope of the disclosure.

The disclosure may provide an apparatus for depositing a two-dimensional material which increases deposition uniformity.

The disclosure may provide an apparatus for depositing a two-dimensional material which limits and/or prevents a dielectric window from being contaminated.

The disclosure may provide an apparatus for depositing a two-dimensional material which forms a high-quality deposition film.

However, effects of the disclosure are not limited to the above disclosure.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope as defined by the following claims.

What is claimed is:

1. An apparatus for depositing a two-dimensional material, the apparatus comprising:
a chamber;
a stage in the chamber;
a dielectric window including a first surface facing the stage and a second surface provided on a side opposite to the first surface;
a planar high-frequency antenna on the second surface of the dielectric window; and
a first gas nozzle configured to provide a source gas into the chamber,
wherein an alternating current electric signal having a frequency of about 1 MHz to about 1 GHz is applied to the planar high-frequency antenna.

2. The apparatus of claim 1, further comprising:
a second gas nozzle in a region adjacent to an edge of the first surface of the dielectric window,
wherein the second gas nozzle provides an inert gas in the chamber.

3. The apparatus of claim 1, further comprising:
a third gas nozzle in a region adjacent to a center of the first surface of the dielectric window,
wherein the third gas nozzle provides an inert gas in the chamber.

4. The apparatus of claim 1, wherein
the first gas nozzle comprises a plurality of first gas nozzles, and
the plurality of first gas nozzles are arranged at regular intervals in a circumferential direction of an inner surface of the chamber.

5. The apparatus of claim 1, wherein the first gas nozzle further provides an inert gas in the chamber.

6. The apparatus of claim 1, further comprising:
a nozzle heating unit configured to heat the first gas nozzle.

7. The apparatus of claim 6, wherein the nozzle heating unit heats the first gas nozzle to a temperature of about 700° C. to about 1,000° C.

8. The apparatus of claim 1, further comprising:
a window heating unit configured to heat the dielectric window.

9. The apparatus of claim 8, wherein the window heating unit heats the dielectric window to about 700° C. to about 1,000° C.

10. The apparatus of claim 1, wherein the stage performs a rotational motion, an ascending motion, or a descending motion.

11. The apparatus of claim 1, wherein a basic bias power less than or equal to about 3,000 watts is applied to the stage.

12. The apparatus of claim 11, wherein an additional bias power less than or equal to about 100 watts is applied to the stage.

13. The apparatus of claim 1, wherein
the first gas nozzle is arranged at a level spaced apart from the planar high-frequency antenna by a first distance in a direction from the planar high-frequency antenna toward the dielectric window, and
the first distance is 5% to 95% of a distance between the planar high-frequency antenna and the stage.

14. The apparatus of claim 1, further comprising:
a deposition substrate on the stage; and
a stage heater configured to heat the deposition substrate.

15. The apparatus of claim 14, wherein the stage heater is configured to heat the deposition substrate to about 550° C. or less.

16. The apparatus of claim 1, wherein the dielectric window includes a high-density insulating material.

17. The apparatus of claim 16, wherein the dielectric window includes a quartz sapphire, boron nitride, or a ceramic material.

18. The apparatus of claim 1, wherein the chamber includes an aluminum-based metal, a stainless steel-based metal, an alloy, an oxide, or a nitride.

19. The apparatus of claim 1, further comprising:
a deposition substrate located on the stage to provide a region on which a two-dimensional material is deposited,
wherein the two-dimensional material includes graphene, a two-dimensional transition metal chalcogen compound, amorphous boron nitride (a-BN), cubic boron nitride (c-BN), or hexagonal boron nitride (h-BN), and
the two-dimensional transition metal chalcogen compound includes MoS₂, MoSe₂, MoTe₂, WS₂, WSe₂, PdSe₂, PdTe₂, PtSe₂, ReSe₂, VSe₂, phosphorene, borophene, stanene, tellurene, or mxene.

20. The apparatus of claim 1, wherein the first gas nozzle discharges the source gas to a position spaced apart from the planar high-frequency antenna by 5% to 95% of a distance between the planar high-frequency antenna and the stage.
